(19) United States
(12) Patent Application Publication
(10) Pub. No.: US 2024/0395574 A1
(43) Pub. Date: Nov. 28, 2024

(54) LASER DEVICE AND METHOD OF MANUFACTURING DISPLAY DEVICE USING THE SAME

(71) Applicant: Samsung Display Co., Ltd., Yongin-Si (KR)

(72) Inventors: DEOKJAE KIM, Yongin-si (KR); HEEGWAN RYU, Yongin-si (KR); Bongyeon LEE, Yongin-si (KR)

(21) Appl. No.: 18/440,971

(22) Filed: Feb. 14, 2024

(30) Foreign Application Priority Data
May 24, 2023 (KR) 10-2023-0067256

(51) Int. Cl. H01L 21/67; H01L 21/02; H01L 21/66; H01S 3/13; H01S 3/225; H01S 3/23; H10K 59/12

(52) U.S. Cl. CPC H01L 21/67115; H01L 21/02686; H01L 21/67253; H01L 22/20; H01S 3/1305; H01S 3/225; H01S 3/2383; H10K 59/1201

(57) ABSTRACT

A method of manufacturing a display device is disclosed that includes oscillating a plurality of laser beams from a plurality of laser generators, measuring first parameters of each of the laser beams by a first measuring unit, measuring second parameters of each of the laser beams after passing through an optical system by a process measuring unit, obtaining optical functions through the first parameters and the second parameters, obtaining a correction function, using the optical functions, and irradiating a substrate with the laser beams, based on the optical functions and the correction.

### CROSS-REFERENCE TO RELATED APPLICATIONS

This U.S. non-provisional patent application claims priority under 35 U.S.C. § 119of Korean Patent Application No. 10-2023-0067256, filed on May 24, 2023, the entire contents of which are hereby incorporated by reference.

### BACKGROUND

The present disclosure relates to a laser device and a method of manufacturing a display device using the same.

Portable display devices are widely used in various fields. As such portable display devices, tablet personal computers, as well as small-sized display devices such as mobile phones, are broadly used.

The portable display devices may include a display panel capable of supporting various functions and providing users with visual information such as images or videos. As other components for driving the display panel have become smaller, the display panel has taken up a greater proportion of a display device lately, and a structure capable of being bent by a predetermined angle from a flat state is under development.

The display panel as described above may include a variety of thin film transistors. In this case, the performance or image quality of the display panel may depend on how precisely the thin film transistors are manufactured.

### SUMMARY

The present disclosure may provide a laser device having improved crystallization reliability of a silicon film in the manufacture of a thin film transistor, and a method of manufacturing a display device using the same.

An embodiment of a method of manufacturing a display device includes oscillating a plurality of laser beams from a plurality of laser generators, measuring first parameters of each of the laser beams by a first measuring unit, measuring second parameters of each of the laser beams after passing through an optical system by a process measuring unit, obtaining optical functions through the first parameters and the second parameters, obtaining a correction function, using the optical functions, and irradiating a substrate with the laser beams, based on the optical functions and the correction.

An embodiment of a laser device includes laser generators configured to oscillate a plurality of laser beams, a first measuring unit configured to measure parameters of each of the laser beams, a blocking unit configured to selectively block the laser beams oscillated from the laser generator, an optical system configured to mix the laser beams emitted from the laser generator into a single process laser beam, and a process measuring unit configured to measure parameters of the laser beams emitted from the optical system and the process laser beam.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a laser device according to an embodiment of the inventive concept;

FIG. 2 is a block diagram showing a control flow of the laser device shown in FIG. 1;

FIG. 3 is a flowchart showing a control sequence of the laser device shown in FIG. 1;

FIGS. 4A, 4B, and 4C are graphs for describing an optical function;

FIGS. 5A and 5B are graphs for describing a correction function;

FIG. 6 is a graph for describing changes in the waveform of a process laser beam according to a time point where an optical system is replaced;

FIGS. 7A and 7B are graphs for describing an unusual waveform of a second process laser beam;

FIG. 8A is a TEM (transmission electron microscope image) image for describing a silicon film crystallized by a laser device according to comparative examples;

FIG. 8B is a TEM image for describing a silicon film crystallized by a laser device according to examples of the inventive concept;

FIG. 9 is a perspective view of a display device manufactured by the laser device shown in FIG. 1;

FIG. 10 is an exploded perspective view of the display device shown in FIG. 9;

FIG. 11 is a cross-sectional view of a display module shown in FIG. 10;

FIG. 12 is a plan view of a display panel shown in FIG. 11; and

FIG. 13 is a view showing a cross-section of the display panel corresponding to any one pixel shown in FIG. 12 as an example.

### DETAILED DESCRIPTION

Advantages and features of the present disclosure and methods of accomplishing the same may be understood more readily by reference to the following detailed description of embodiments and the accompanying drawings. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Further, the present disclosure is only defined by scopes of claims. Like reference numerals denote like elements throughout specification.

When an element or layer is referred to as being “on” another element or layer, it can be directly on another element or layer, or intervening elements or layers may also be present. In contrast, when an element is referred to as being “directly on” or “right above” another element, there are no intervening elements present.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Like reference numerals denote like elements throughout specification.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the inventive concepts.

The embodiments in this specification will be described with reference to plan views and cross-sectional views as ideal schematic views of the present disclosure. Therefore, a form of an example view may be modified by a manufacturing method or tolerance. Accordingly, the embodiments of the present disclosure are not limited to the specific shape illustrated in the example views, but may include other shapes that are created according to manufacturing processes. Thus, areas exemplified in the drawings have general properties, and shapes of the exemplified areas are used to illustrate a specific shape of a device region. Thus, this should not be construed as limited to the scope of the present disclosure.

Hereinafter, preferred embodiments of the inventive concept will be described in detail with reference to the accompanying drawings.

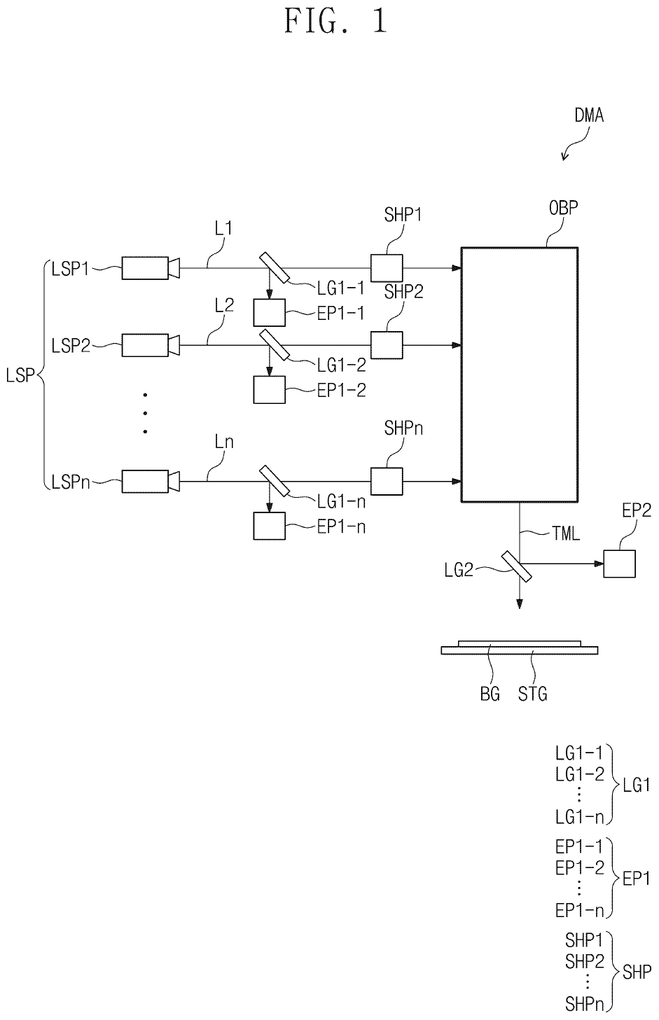

FIG. 1 is a laser device according to an embodiment of the inventive concept.

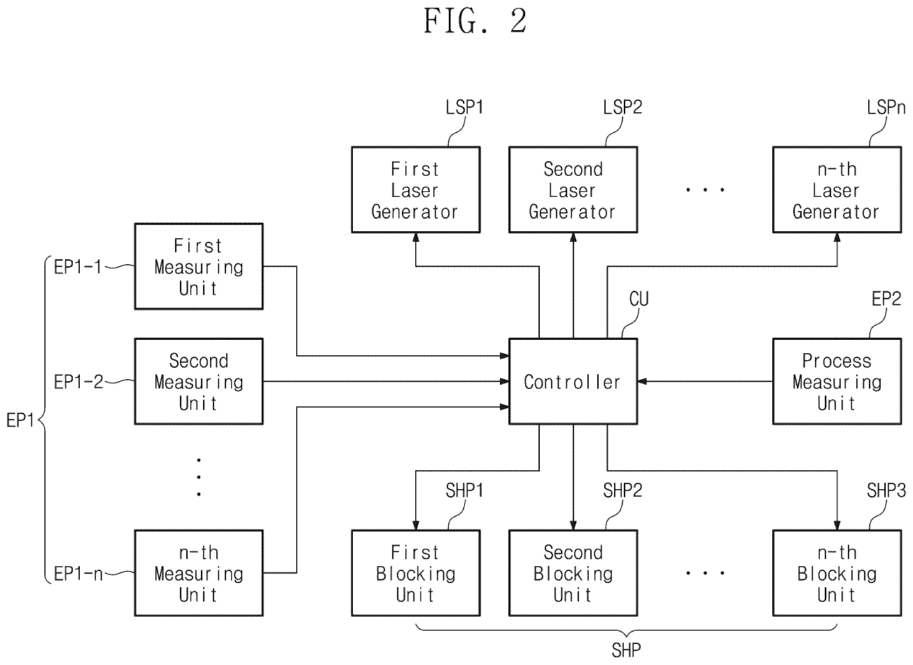

FIG. 2 is a block diagram showing a control flow of the laser device shown in FIG. 1.

Referring to FIG. 1, a laser device DMA may include a laser generator LSP, a first measuring unit EP1, a first laser guide unit LG1, a blocking unit SHP, an optical system OBP, a second laser guide unit LG2, a process measuring unit EP2, and a stage STG.

The laser generator LSP may oscillate laser beams of the same type. The laser generator LSP may oscillate excimer laser beams.

The laser generator LSP may include a first laser generator LSP1 to an n-th laser generator LSPn. n may be a natural number. The first to n-th laser generators LSP1 to LSPn may each be disposed to be spaced apart.

The first to n-th laser generators LSP1 to LSPn may each emit laser beams. The first to n-th laser generators LSP1 to LSPn may each emit excimer laser beams. As an example, the first laser generator LSP1 may emit a first laser beam L1. The second laser generator LSP2 may emit a second laser beam L2. The n-th laser generator LSPn may emit an n-th laser beam Ln.

The first to n-th laser beams L1 to Ln may be the same type. As an example, parameters of each of the first laser beam L1 to the n-th laser beam Ln may be the same. However, the embodiment of the inventive concept is not limited thereto, and parameters of each of the first laser beam L1 to the n-th laser beam Ln may be different.

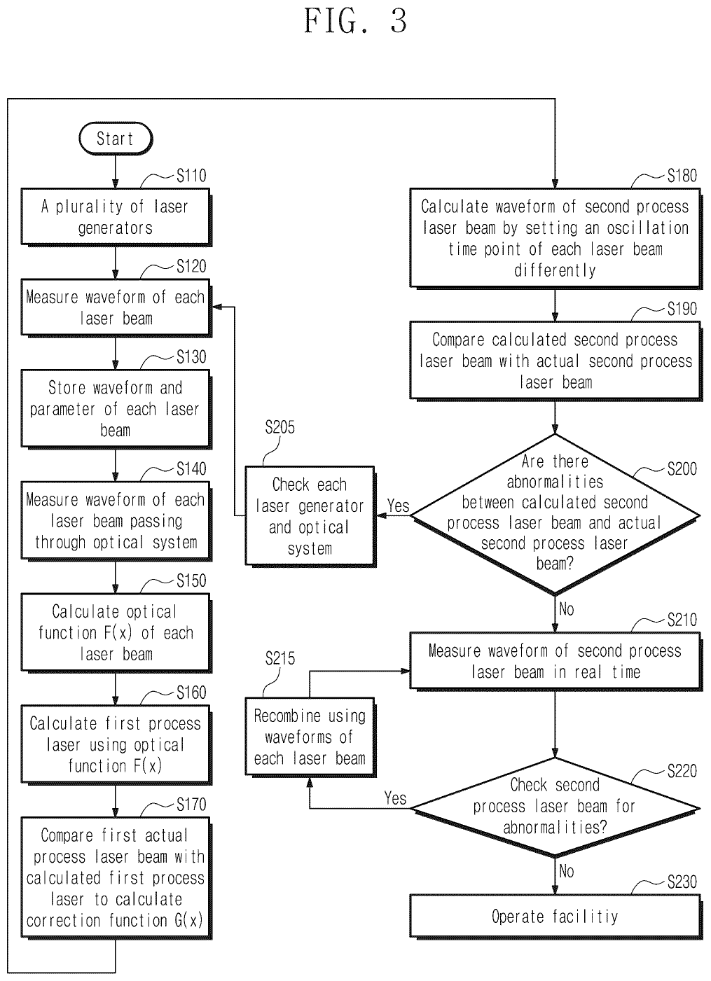

At least two of the first to n-th laser beams L1 to Ln may have different oscillation time points. The oscillation time points of the first laser beam L1 to the n-th laser beam Ln will be described in detail with reference to FIG. 3.

The first laser guide unit LG1 may make some of the laser beams L1 to Ln oscillated from the laser generator LSP pass, and refract other some. In this case, the first laser guide unit LG1 may include a half mirror.

However, this is presented as an example, and the first laser guide unit LG1 may be rotatably arranged to reflect the laser beams L1 to Ln oscillated from the laser generator LSP, thereby altering the traveling path of the laser beams L1 to Ln. In addition, the first laser guide unit LG1 may include a plurality of half mirrors or mirrors, and the laser beams L1 to Ln may be reflected from the half mirrors or mirrors, so that the traveling path of the laser beams L1 to Ln may be altered.

The first laser guide unit LG1 may be provided in plurality. The first laser guide unit LG1 may include a (1-1)-th laser guide unit LG1-1 to a (1-n)-th laser guide unit LG1-n. The (1-1)-th laser guide unit LG1-1 to (1-n)-th laser guide unit LG1-n may be disposed to be spaced apart.

The (1-1)-th laser guide unit LG1-1 to (1-n)-th laser guide unit LG1-n may each alter the traveling path of corresponding laser beams L1 to Ln among the first to n-th laser beams L1 to Ln.

Some of the laser beams L1 to Ln whose travel path is altered may be incident toward the first measuring unit EP1. The first measuring unit EP1 may detect some of the laser beams L1 to Ln. The first measuring unit EP1 may detect some of the laser beams L1 to Ln to measure parameters of each of the laser beams L1 to Ln.

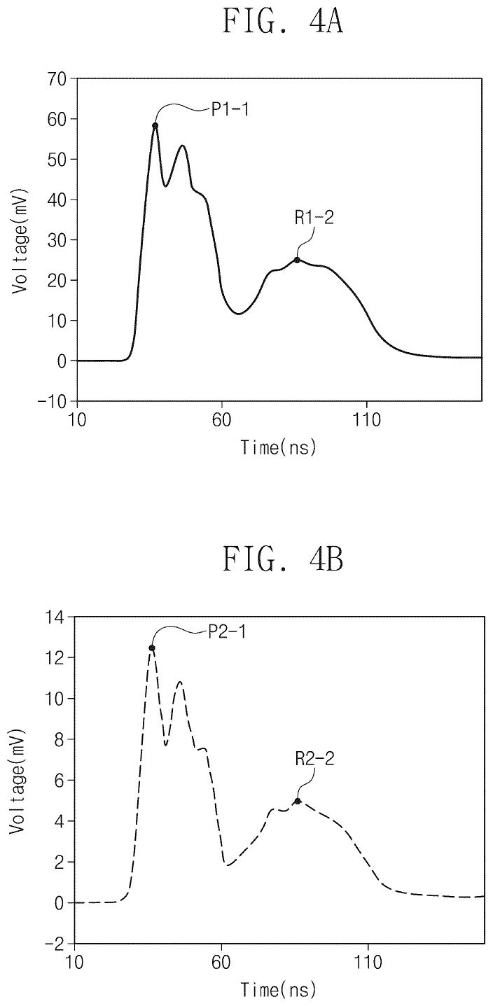

As an example, the parameters may each include values for pulse max intensity, pulse 2^{nd} hump max intensity, and time integral of pulse. The parameters will be described in detail in FIGS. 4A to 4C.

The first measuring unit EPI may be provided in plurality. The first measuring unit EP1 may include a (1-1)-th measuring unit EP1-1 to a (1-n)-th measuring unit EP1-n. The (1-1)-th measuring unit EP1-1 to (1-n)-th measuring unit EP1-n may each include a photodiode or the like.

The (1-1)-th measuring unit EP1-1 to (1-n)-th measuring unit EP1-n may each measure parameters of corresponding laser beams L1 to Ln among some of the laser beams L1 to Ln.

Among the laser beams L1 to Ln, the laser beams L1 to Ln passing through the first laser guide unit LG1 may be incident to the blocking unit SHP. The blocking unit SHP may block the laser beams L1 to Ln from being incident to the optical system OBP, which will be described later.

The blocking unit SHP may be provided in plurality. The blocking unit SHP may include first to n-th blocking units SHP1 to SHPn. The first to n-th blocking units SHP1 to SHPn may be disposed to be spaced apart.

The first to n-th blocking units SHP1 to SHPn may block corresponding laser beams L1 to Ln among the first to n-th laser beams L1 to Ln. The first blocking unit SHP1 to the n-th blocking unit SHPn may selectively block the laser beams L1 to Ln.

As an example, when the first to n-th blocking units SHP1 to SHPn block the laser beams L1 to Ln, a first mode may be defined. As an example, when the first to n-th blocking units SHP1 to SHPn allow the laser beams L1 to Ln pass, a second mode may be defined.

Only any one of the first to n-th blocking units SHP1 to SHPn may be in the second mode at a given time, and the other blocking units SHP1 to SHPn may be in the first mode. In this case, except for any one of the laser beams L1 to Ln, the other laser beams L1 to Ln may not be incident to the optical system OBP, which will be described later, by the first to n-th blocking units SHP1 to SHPn. However, the embodiment of the inventive concept is not limited thereto, and when crystallizing a silicon film on a substrate BG, which will be described later, all of the first to n-th blocking units SHP1 to SHPn may be in the second mode. This will be described in detail in FIG. 3.

The optical system OBP may mix the laser beams L1 to Ln oscillated from the laser generator LSP. The optical system OBP may mix the laser beams L1 to Ln to generate a process laser beam TML.

Although not shown, as an example, the optical system OBP may include a plurality of lenses, a beam splitter, a reflective mirror, and the like. The optical system OBP may use the plurality of lenses, the beam splitter, the reflection mirror, and the like to polarize one of the laser beams L1 to Ln or alter the traveling path thereof, thereby mixing the laser beams L1 to Ln.

The substrate BG disposed on the stage STG, which will be described later, may be irradiated with the process laser beam TML generated from the optical system OBP. In this case, the second laser guide unit LG2 may be disposed between the optical system OBP and the substrate BG.

The second laser guide unit LG2 may serve the same function as the first laser guide unit LG1. Specifically, the second laser guide unit LG2 may alter the traveling path of a portion of the process laser beam TML.

A portion of the process laser beam TML may be incident toward the process measuring unit EP2 by the second laser guide unit LG2. As an example, the process measuring unit EP2 may measure parameters of the process laser beam TML. The process measuring unit EP2 may measure values for pulse max intensity, pulse 2^{nd} hump max intensity, and time integral of pulse of the process laser beam TML.

In FIG. 1, the process measuring unit EP2 is shown to measure parameters of the process laser beam TML, but may not be limited thereto. Specifically, when only any one of the laser beams L1 to Ln is incident to the optical system OBP by the blocking unit SHP, any one of the laser beams L1 to Ln from the optical system OBP may be incident to the process measuring unit EP2. In this case, the process measuring unit EP2 may measure parameters of any one of the laser beams L1 to Ln, which passes through the optical system OBP.

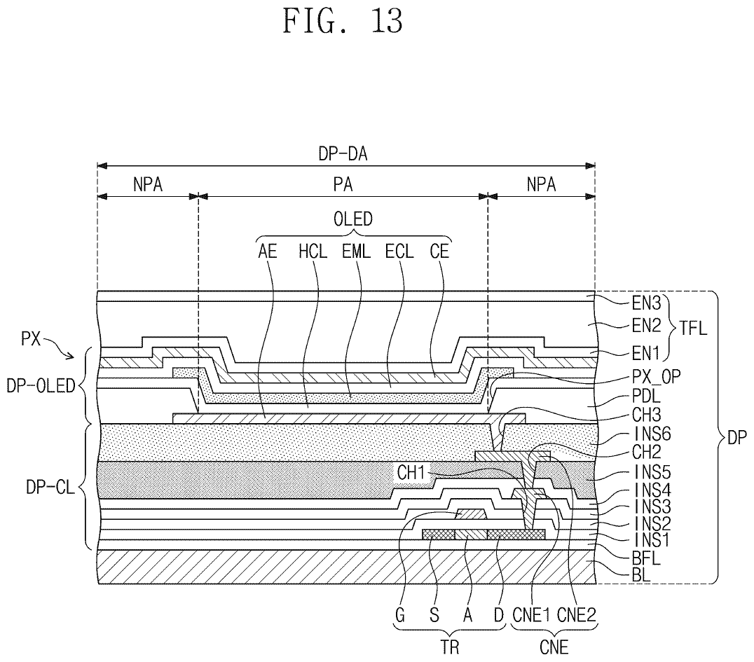

The stage STG may be disposed below the optical system OBP. The stage STG may be disposed to face the optical system OBP. The substrate BG may be placed on the stage STG. The substrate BG may be defined by a base layer BL and a circuit element layer DP-CL, which will be described with reference to FIG. 13.

The process laser beam TML may be incident to the substrate BG. The process laser beam TML may perform a process of crystallizing a silicon film on the substrate BG. This will be described in detail in FIG. 3.

Referring to FIGS. 1 and 2, the laser device DMA may further include a controller CU. The controller CU may be in various forms. As an example, the controller CU may include one of a mobile phone, a laptop computer, a portable terminal, or a personal computer, which will be separately provided. In addition, the controller CU may include a circuit board or the like.

The first measuring unit EP1 and the process measuring unit EP2 may transmit information on parameters of the laser beams L1 to Ln to the controller CU. The controller CU may calculate an optical function through information on parameters. The optical function may be defined as waveforms of the first to n-th laser beams L1 to Ln, which change as the first to n-th laser beams L1 to Ln pass through the optical system OBP. This will be described in detail in FIG. 3.

The controller CU may control the laser generator LSP. The controller CU may control an oscillation time point (or time) of each of the first to n-th laser generators LSP1 to LSPn in various forms. This will be described in detail in FIG. 3.

The controller CU may control the light blocking unit SHP.

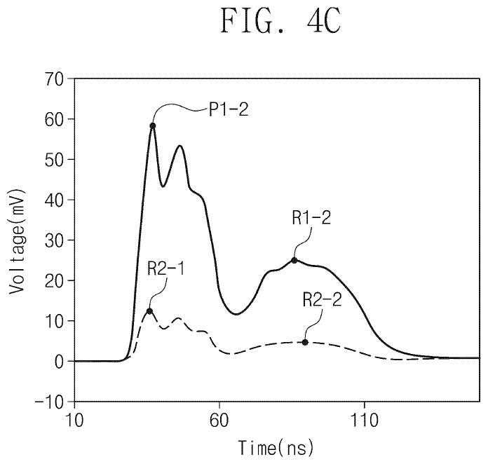

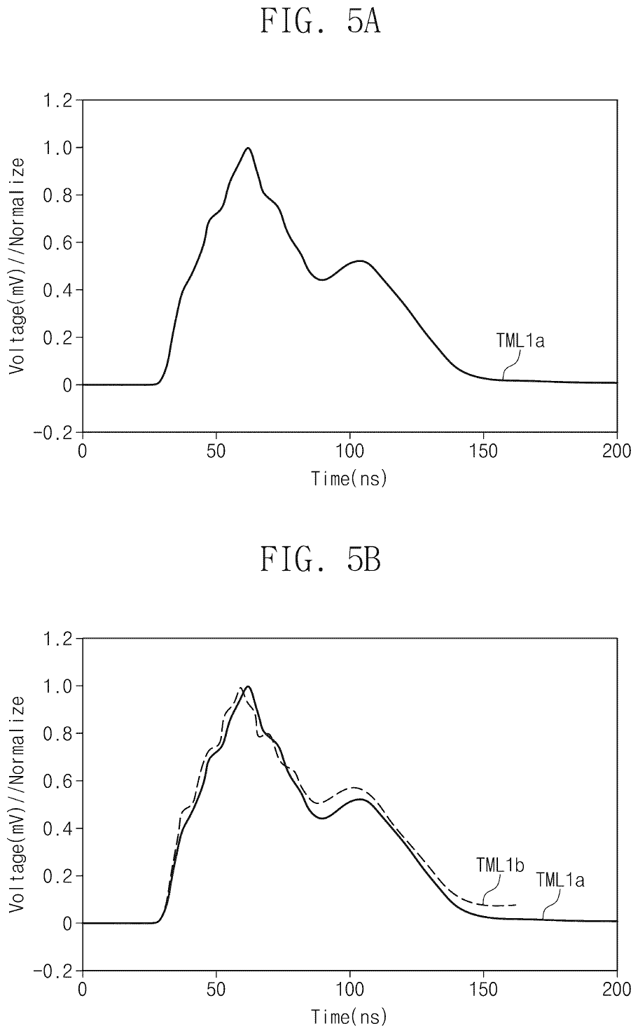

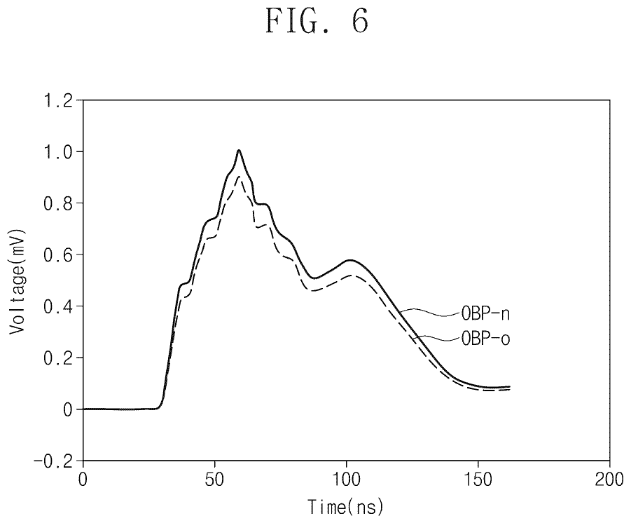

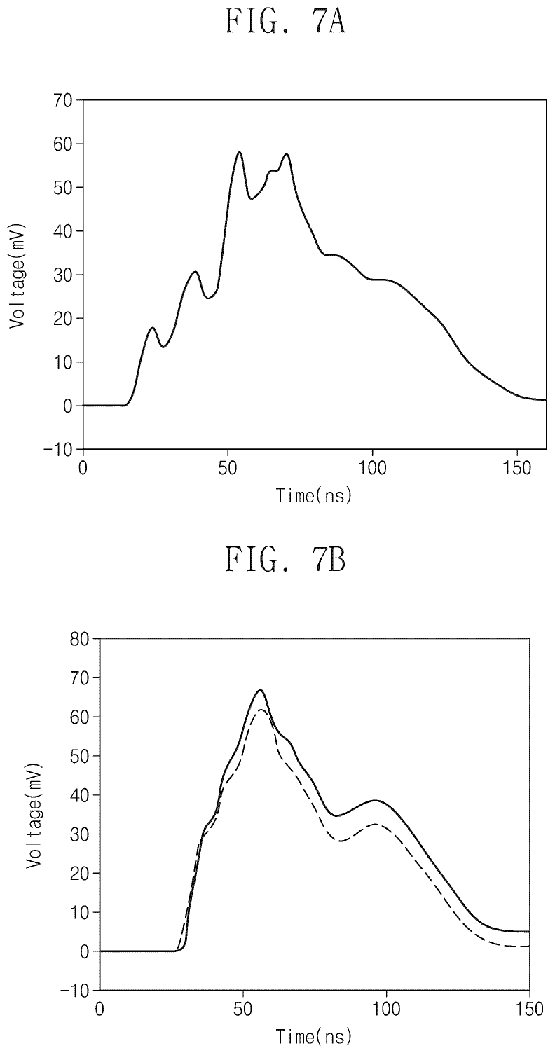

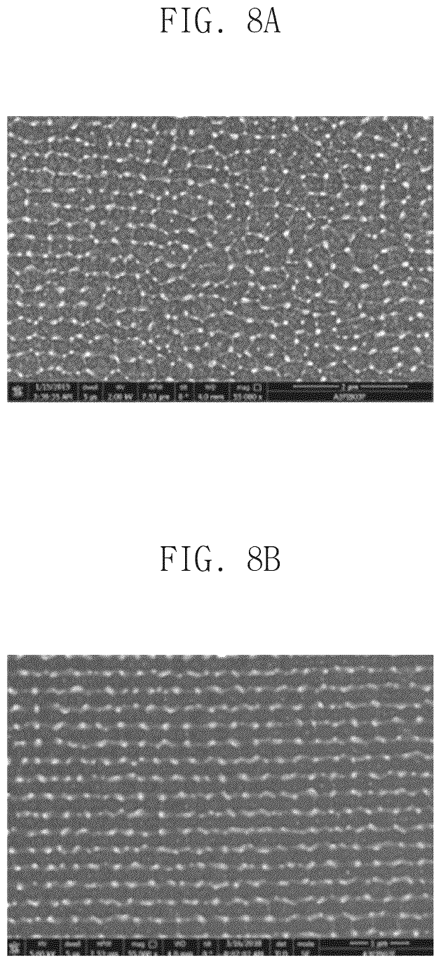

FIG. 3 is a flowchart showing a control sequence of the laser device shown in FIG. 1. FIGS. 4A to 4C are graphs for describing an optical function. FIGS. 5A and 5B are graphs for describing a correction function. FIG. 6 is a graph for describing changes in waveform of a process laser beam according to a time point where an optical system is replaced. FIGS. 7A and 7B are graphs for describing an unusual waveform of a second process laser beam. FIG. 8A is a TEM (transmission electron microscope) image for describing a silicon film crystallized by a laser device according to Comparative Examples. FIG. 8B is a TEM image for describing a silicon film crystallized by a laser device according to Examples of the inventive concept. The graphs of FIGS. 4A to 4C, 5A, 5B, 6, 7A, and 7B show light intensity as voltage output from measuring unit EP.

As an example, a laser generator LSP, a first laser guide unit LG1, a first measuring unit EP1, a blocking unit SHP, an optical system OBP, a second laser guide unit LG2, and a process measuring unit EP2, which are shown in FIG. 3, are the same as the laser generator LSP, the first laser guide unit LG1, the first measuring unit EP1, the blocking unit SHP, the optical system OBP, the second laser guide unit LG2, and the process measuring unit EP2, which are shown in FIG. 1, and thus description thereof will be simplified or will not be provided.

As an example, in FIGS. 5A and 5B, a first theoretical parameter is shown in solid line and a first actual parameter is shown in dotted line.

As an example, in FIG. 6, a waveform OBP-n of a process laser passing through an optical system immediately after replacement is shown in solid line, and a waveform OBP-o of a process laser passing through an optical system immediately before replacement is shown in dotted line.

In FIG. 7B, an actual waveform of a second process laser is shown in solid line, and a calculated second unusual waveform is shown in dotted line.

Referring to FIGS. 1 and 3, a method of manufacturing a display device may include turning on power of laser generators LSP1 to LSPn (S110). When the laser generators LSP1 to LSPn are turned on, the laser generators LSP1 to LSPn may each oscillate first to n-th laser beams L1 to Ln.

In this case, the oscillation time points of the first to n-th laser beams L1 to Ln may be the same. As the oscillation time points of the first to n-th laser beams L1 to Ln are the same, optical functions and correction functions, which will be described later, may be precisely calculated.

Referring to FIGS. 1 to 3, and 4A, the laser beams L1 to Ln oscillated from the laser generators LSP1 to LSPn are incident to the first measuring unit EP1 by the first laser guides LG1.

When the laser beams L1 to Ln are incident toward the first measuring unit EP1, measuring waveforms and parameters of each of the laser beams L1 to Ln (S120) may be performed. As shown in FIG. 4A, the first measuring unit EP1 may measure the waveform of each of the laser beams L1 to Ln. As an example, in FIG. 4A, a waveform of any one of the laser beams L1 to Ln is shown.

The first measuring unit EP1 may obtain parameters of each of the laser beams L1 to Ln through the waveforms of the laser beams L1 to Ln. The parameters of each of the laser beams L1 to Ln measured through the first measuring unit EP1 may be defined as first parameters.

The first parameters may each include values for pulse max intensity, pulse 2^{nd} hump max intensity, and time integral of pulse.

As an example, as shown in FIG. 4A, the pulse max intensity of the first parameter may be defined as a point P1-1 that is a maximum voltage on the graph. The pulse 2^{nd} hump max intensity of the first parameter may be defined as a point P1-2 that is a second greatest voltage on the graph. The time integral of pulse of the first parameter may be defined as an area of a lower surface of the graph in the graph of time and voltage intensity shown in FIG. 4A.

The first measuring unit EP1 may measure values for pulse max intensity, pulse 2^{nd} hump max intensity, and time integral of pulse of each of the laser beams L1 to Ln. After the first parameters are measured, storing the first parameters in the controller CU (S130) may be performed.

Referring to FIGS. 1 to 3, and 4B, after the measuring of the first parameters, measuring the waveform of each of the laser beams L1 to Ln passing through the optical system OBP by the process measuring unit EP2 (S140) may be performed.

The laser beams L1 to Ln passing through the first laser guide unit LG1 may be directed to the blocking units SHP1 to SHPn. In this case, any one of the blocking units SHP1 to SHPn may be in the second mode. Among the blocking units SHP1 to SHPn, the other blocking units SHP1 to SHPn may be in the first mode. Accordingly, only any one of the laser beams L1 to Ln may be incident to the optical system OBP.

Any one of the laser beams L1 to Ln passing through the optical system OBP may be incident to the process measuring unit EP2 through the second laser guide unit LG2. The process measuring unit EP2 may measure the waveform of any one laser beam L1 to Ln passing through the optical system OBP. The process measuring unit EP2 may obtain parameters of any one of the laser beam L1 to Ln passing through the optical system OBP through the waveform of the laser beams L1 to Ln. The parameter measured through the process measuring unit EP2 may be defined as a second parameter.

The second parameters may include values for pulse max intensity, pulse 2^{nd} hump max intensity, and time integral of pulse.

As an example, as shown in FIG. 4B, the pulse max intensity of the second parameter may be defined as a maximum voltage point P2-1. The pulse 2^{nd} hump max intensity of the second parameter may be defined as a point P2-2 that is a second greatest voltage. The time integral of pulse of the second parameter may be defined as an area of a lower surface of the graph shown in FIG. 4B. The second parameter measured by the process measuring unit EP2 may be stored in the controller CU.

Although the process of obtaining the second parameter of any one of the laser beams L1 to Ln is described as an example, each of the laser beams L1 to Ln undergoes the same process described in FIG. 4B, and the process measuring unit EP2 may obtain the second parameters of all laser beams L1 to Ln.

Referring to FIGS. 2 and 4A to 4C, that the controller CU calculates optical functions through the first parameters obtained by the first measurement unit EP1 and the second parameters obtained by the process measurement unit EP2 (S150) may be performed.

Specifically, each of the pulse max intensity P1-1 of the first parameters may be compared with the pulse max intensity P2-1 of a corresponding second parameter among the second parameters by the controller CU. The controller CU may compare the pulse max intensity P1-1 of the first parameters and the pulse max intensity P2-1 of the second parameters to obtain first numerical values.

Each of the pulse 2^{nd} hump max intensity P1-2 of the first parameters may be compared with the pulse 2^{nd} hump max intensity P2-2 of a corresponding second parameter among the second parameters by the controller CU. The controller CU may compare the pulse 2^{nd} hump max intensity P1-2 of the first parameters and the pulse 2^{nd} hump max intensity P2-2 of the second parameters to obtain second numerical values.

Each of the time integral of pulse of the first parameters may be compared with the time integral of pulse of a corresponding second parameter among the second parameters by the controller CU. The controller CU may compare the time integral of pulse of the first parameters with the time integral of pulse of the second parameters to obtain third numerical values.

As an example, the controller CU may calculate an optical function F(x), using the first, second, and third numerical values obtained from any one of the laser beams L1 to Ln. Specifically, the controller CU may calculate the optical function F(x), using an average value of the first, second, and third numerical values obtained from any one of the laser beams L1 to Ln.

Although any one of the laser beams L1 to Ln is described, the controller CU may calculate the optical functions F(x) of each of the laser beams L1 to Ln, using the first numerical values, the second numerical values, and the third numerical values of each of the laser beams L1 to Ln.

Referring to FIGS. 1, 2, 3, and 5A and 5B, after the optical functions F(x) are calculated, the laser beams L1 to Ln may be oscillated at the same oscillation time point to pass through the blocking unit SHP. In this case, all of the first to n-th blocking units SHP1 to SHPn may be in the second mode.

The laser beams L1 to Ln oscillated at the same oscillation time point may pass through the blocking unit SHP and be incident to the optical system OBP. The laser beams L1 to Ln incident to the optical system OBP may be mixed by the optical system OBP. Hereinafter, a mixture of the laser beams L1 to Ln oscillated at the same oscillation time point may be defined as a first process laser beam.

Thereafter, calculating the waveform and parameters of the first process laser beam by the controller CU (S160) may be performed. The controller CU may calculate a waveform TML1a and a parameter of the first process laser beam, using the optical functions F(x).

The waveform of the first process laser beam calculated through the optical functions F(x) may be defined as a (1-1)-th waveform TML1a, and the parameter of the first process laser beam calculated through the optical functions F(x) may be defined as a first theoretical parameter.

After the waveform TML1a and the first theoretical parameter of the (1-1)-th process laser beam are obtained, an actual waveform and parameter of the first process laser beam may be measured by the process measuring unit EP2. The waveform of the first process laser beam measured by the process measuring unit EP2 may be defined as a (1-2)-th waveform TML1b. The parameter of the first process laser beam measured by the process measuring unit EP2 may be defined as a first actual parameter.

After the obtaining of the first theoretical parameter and the first actual parameter, comparing the (1-1)-th waveform TML1a with the (1-2)-th waveform TML1b, and the first theoretical parameter with the first actual parameter by the controller CU (S170) may be performed.

As shown in FIG. 5B, the (1-1)-th waveform TML1a and the (1-2)-th waveform TML1b may be different. When the laser beams L1 to Ln are incident to the optical system OBP, the first theoretical parameter and the first actual parameter may be different. The controller CU may compare the first theoretical parameter with the first actual parameter.

The controller CU may calculate a correction function G(x) so that the first theoretical parameter matches the first actual parameter.

Referring to FIGS. 1 to 3, after the calculating of the optical functions F(x) and the correction function G(x) by the controller CU, the laser beams L1 to Ln may be oscillated at different oscillation time points. In this case, the oscillation time points of the laser beams L1 to Ln may be regulated through the controller CU. The controller CU may determine an oscillation time point of each of the laser beams L1 to Ln, using the optical functions F(x) and the correction function G(x).

At least two of the laser beams L1 to Ln may have different oscillation time points. As an example, the oscillation time point of at least one of the laser beams L1 to Ln may be different from the oscillation time point of the other laser beams L1 to Ln. However, the embodiment of the inventive concept is not limited thereto, and the oscillation time points of all the laser beams L1 to Ln may be different.

The laser beams L1 to Ln oscillated at different oscillation time points may be mixed by the optical system OBP. The mixture of the laser beams L1 to Ln oscillated at different oscillation time points may be defined as a second process laser beam.

After the second process laser beam is generated, calculating a waveform and a parameter of the second process laser beam by the controller CU (S180) may be performed. The controller CU may calculate the waveform and parameter of the second process laser beam, using the optical functions F(x) and the correction function G(x). The controller CU may calculate the parameter of the second process laser beam through the calculated waveform of the second process laser beam. The parameter of the second process laser beam calculated by the controller CU may be defined as a second theoretical parameter.

Referring to FIGS. 1, 3, and 6, after the obtaining of the second theoretical parameter, comparing the second theoretical parameter with the second actual parameter by the controller CU (S190) may be performed.

The comparing of the second theoretical parameter with the second actual parameter (S190) may include measuring an actual waveform and an actual parameter of the second process laser beam. Specifically, the process measuring unit EP2 may measure an actual waveform of the second process laser beam. The process measuring unit EP2 may obtain an actual parameter of the second process laser beam through an actual waveform of the second process laser beam. The parameter of the second process laser beam obtained by the process measuring unit EP2 may be defined as a second actual parameter.

The controller CU may compare the second theoretical parameter with the second actual parameter. After the obtaining of the actual waveform and the second actual parameter of the second process laser beam and comparing the calculated waveform of the second process laser beam with the actual waveform of the second process laser beam, the controller determines whether there are abnormalities (S200).

The second theoretical parameter and the second actual parameter are compared, and when the second theoretical parameter is out of a predetermined range from the second actual parameter, checking the optical system OBP or the laser generators LSP1 to LSPn oscillating the individual laser beams L1 to Ln (S205) may be performed.

There may be various causes for the second theoretical parameter to be out of a predetermined range from the second actual parameter. For example, when the optical system OBP is aged, the second theoretical parameter may be out of set range to a greater extent.

Specifically, immediately after replacing the optical system OBP, an optical function F(x) and a correction function G(x) may be obtained from the first parameters and the second parameters of each of the individual laser beams L1 to Ln. Hereinafter, the optical function F(x) and the correction function G(x) obtained by passing the laser beams L1 to Ln through the optical system OBP immediately after replacement may be defined as a first optical function F(x)₁ and a first correction function G(x)₁.

An optical function F(x) and a correction function G(x) may be obtained from the first parameters and the second parameters of each of the individual laser beams L1 to Ln passing through the aged optical system OBP, which is about to be replaced, may be calculated. Hereinafter, the optical function F(x) and the correction function G(x) obtained by passing the laser beams L1 to Ln through the optical system OBP, which is about to be replaced, may be defined as a first optical function F(x)₂ and a first correction function G(x)₂.

The waveform of the second process laser beam calculated using the first optical function F(x)₁ and the first correction function G(x)₁ may be defined as a (2-1)-th waveform OBP-n. The waveform of the second process laser calculated using the second optical function F(x)₂ and the second correction function G(x)₂ may be defined as a (2-2)-th waveform OBP-o.

When comparing the actual waveform of the second process laser with the (2-1)-th waveform OBP-n and the (2-2)-th waveform OBP-o, the older the optical system OBP, the greater the difference between the second actual parameter and the second theoretical parameter. Accordingly, it is possible to check whether the optical system OBP is aged and required to be replaced. Therefore, the laser device DMA may be easily maintained or managed.

In addition, when the optical functions F(x) is the cause in which the second theoretical parameter is out of a predetermined range from the second actual parameter, traveling paths of the laser beams L1 to Ln before passing through the optical system OBP may be checked. As an example, the first to n-th laser generators LSP1 to LSPn, the first laser guide units LG1, and the first measuring units EP1 may be checked.

When the correction function G(x) is the cause in which the second theoretical parameter is out of set range, traveling paths of the laser beams L1 to Ln after passing through the optical system OBP may be checked. As an example, the second laser guide unit LG2 and the process measuring unit EP2 may be checked.

Through the comparing of the second theoretical parameter with the second actual parameter (S200), the laser device DMA may be checked for abnormalities. Accordingly, the laser device DMA may be easily managed. Therefore, the laser device DMA may oscillate the laser beams L1 to Ln at the set oscillation time point, and the process of crystallizing a silicon film may provide improved reliability.

After the checking of the optical system OBP or the laser generators LSP1 to LSPn oscillating the individual laser beams L1 to Ln, measuring waveforms of the laser beams L1 to Ln (S120) may be performed.

Referring to FIGS. 1, 3, and 7A and 7B, when the calculated waveform of the second process laser beam is within a predetermined range from the actual waveform of the second process laser beam, and when the second theoretical parameter is within a predetermined range from the second actual parameter, measuring a waveform of the second process laser beam in real time (S210) and checking parameters of the second process laser beam for abnormalities in real time (S220) may be performed.

The controller CU may calculate the waveform and parameter of the second process laser beam in real time. The controller CU may obtain the waveform and parameter of the second process laser beam calculated in real time. The parameter of the second process laser beam calculated in real time by the controller CU may be defined as a third theoretical parameter.

The process measuring unit EP2 may measure the waveform and parameter of the second process laser beam in real time. The parameter of the second process laser beam measured in real time by the process measuring unit EP2 may be defined as a third actual parameter.

The controller CU may compare the third theoretical parameter with the third actual parameter in real time. In real time, the controller CU may compare the calculated waveform of the second process laser with the actual waveform of the second process laser.

When there is an abnormality in the waveform and the third theoretical parameter of the second process laser, which are calculated in real time, recombining the waveforms of the laser beams L1 to Ln by the controller CU (S215) may be performed.

As an example, when the calculated waveform of the second process laser beam has an abnormal waveform as shown in FIG. 7A, the controller CU may alter the oscillation time point of each of the laser beams L1 to Ln to a different combination from the previously performed oscillation time point. Accordingly, the calculated waveform of the second process laser beam may be altered.

In addition, as shown in FIG. 7B, when the calculated waveform and third theoretical parameter of the second process laser beam are different from the actual waveform and third actual parameter of the second process laser beam, the controller CU may alter the oscillation time point of each of the laser beams L1 to Ln to a different combination from the previously performed oscillation time point. Accordingly, the calculated waveform and third theoretical parameter of the second process laser beam may be altered.

When there is no abnormality in the calculated waveform and third theoretical parameter of the second process laser beam, continuously operating a facility (S230) may be performed. The substrate BG of FIG. 1 may be irradiated with the second process laser beam. A silicon film of the substrate BG may be crystallized by the second process laser beam.

In real time, as the controller CU measures the waveform and the third theoretical parameter of the second process laser beam, the second process laser beam may be checked for abnormalities in real time, and the oscillation time point of the laser beams L1 to Ln may be regulated in real time. Accordingly, the process laser for crystallizing the silicon film of the substrate BG may be checked in real time, and therefore, the crystallization reliability of the silicon film may be improved.

Referring to FIGS. 1, 2, 8A and 8B, the waveform of the process laser beam TML may affect the arrangement of a crystallized silicon film. Specifically, as shown in FIG. 8A, when the waveform of the process laser beam TML is not measured in real time, even when the waveform of the process laser beam TML changes, the controller CU may not be able to control the waveform of the process laser beam TML. Accordingly, the waveform and parameters of the process laser beam TML may not remain in a certain range.

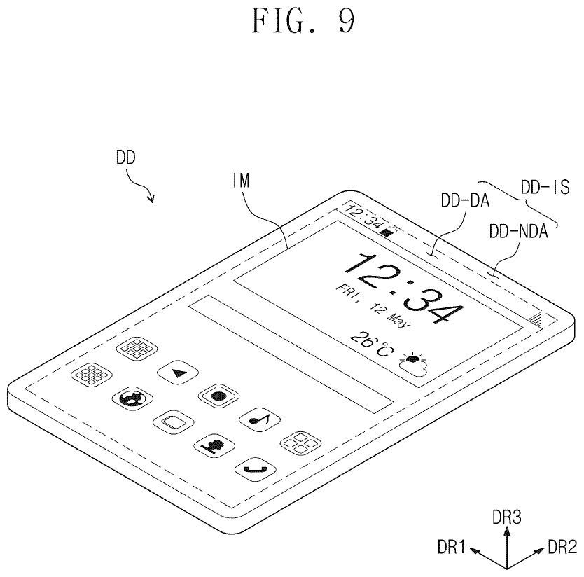

When the parameters of the process laser beam TML do not remain in the certain range, the waveform and parameters of the process laser beam TML suitable for the process of crystallizing a silicon film may not be provided onto the substrate BG. Accordingly, the arrangement of the crystallized silicon film may not be uniform. In this case, the substrate BG may have reduced quality. Therefore, defects in a display device DD (see FIG. 9) may be caused.

However, when the laser device DMA according to an embodiment of the inventive concept is used, the waveform and parameters of the process laser beam TML may be measured in real time. When the waveform and parameters of the process laser beam TML are out of the certain range, in response, the controller CU may control the waveform of the process laser beam TML in real time. Accordingly, the waveform and parameters of the process laser beam TML may be able to remain within the certain range, and the waveform and parameters of the process laser beam TML suitable for the process of crystallizing a silicon film may be provided onto the substrate BG. Therefore, as shown in FIG. 8B, the arrangement of the crystallized silicon film may be uniform, and defects of the display device DD (see FIG. 9) may be reduced.

FIG. 9 is a perspective view of a display device manufactured by the laser device shown in FIG. 1.

Referring to FIG. 9, herein, a mobile phone terminal is shown as an example of the display device DD. The display device DD according to an embodiment of the inventive concept may not only be used for large-sized electronic devices such as television sets and monitors but also used for small- and medium-sized electronic devices such as tablets, car navigation units, game consoles, and smart watches.

The display device DD may have short sides extending in a first direction DR1 and long sides extending in a second direction DR2 crossing the first direction DR1 when viewed on a plane. However, the embodiment of the inventive concept is not limited thereto, and the display device DD may have various shapes such as a circular shape and a polygonal shape.

Hereinafter, a direction substantially perpendicularly crossing a plane defined by the first direction DR1 and the second direction DR2 is defined as a third direction DR3. As used herein, “when viewed on a plane” may be defined as viewed from the third direction DR3.

The display device DD may be rigid or flexible. The term “flexible” indicates a property of being bendable, and may include all from a structure being completely foldable to a structure being bendable up to several nanometers. For example, the flexible display device DD may include a curved electronic device, a rollable electronic device, or a foldable electronic device.

The display device DD may display an image IM through a display surface DD-IS. Icon images are shown as an example of the image IM. The display surface DD-IS may be parallel to a plane defined by a first direction DR1 and a second direction DR2.

The display surface DD-IS may include a display region DD-DA displaying the image IM, and a non-display region DD-NDA adjacent to the display region DD-DA. The non-display region DD-NDA may be a region in which images are not displayed. However, the embodiment of the inventive concept is not limited thereto, and the non-display region DD-NDA may be placed adjacent to any one side of the display region DD-DA, or may be omitted.

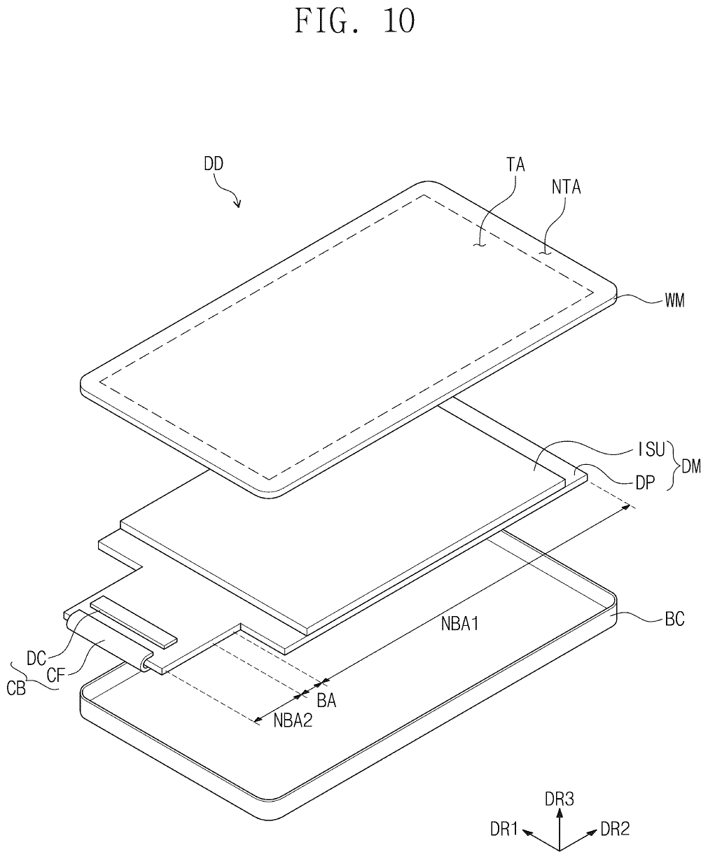

FIG. 10 is an exploded perspective view of the display device shown in FIG. 9.

As an example, FIG. 10 shows a state in which a bending region BA is unfolded.

Referring to FIGS. 9 and 10, the display device DD may include a window WM, a display module DM, and an accommodation member BC.

The window WM may be disposed above the display module DM and transmit images provided from the display module DM to the outside. The window WM may include a transmission region TA and a non-transmission region NTA. The transmission region TA may overlap the display region DD-DA shown in FIG. 9 and may have a shape corresponding to the display region DD-DA. Although not shown, the window WM may include a base layer and functional layers disposed on the base layer. The functional layers may include a protection layer, an anti-fingerprint layer, and the like. The base layer of the window WM may be formed of glass, sapphire, or plastic. The base layer of the window WM may include an optically transparent insulating material. For example, the base layer of the window WM may include glass or plastic films, or may include a glass substrate and a plastic film, which are bonded through an adhesive.

The non-transmission region NTA may overlap the non-display region DD-NDA shown in FIG. 9 and may have a shape corresponding to the non-display region DD-NDA. The non-transmission region NTA may be a region having a relatively lower light transmittance than the transmission region TA. The non-transmission region NTA may be defined by a bezel pattern in a portion of the base layer of the window WM, and a region where the bezel pattern is not disposed may be defined as the transmission region TA. However, the embodiment of the inventive concept is not limited thereto, and the non-transmission region NTA may be omitted.

Although not shown, an anti-reflection layer may be disposed between the window WM and the display module DM. The anti-reflection layer may reduce reflectance of external light incident from the outside of the display device DD. The anti-reflection layer may include color filters. The color filters may have a predetermined arrangement. For example, the color filters may be arranged in consideration of light emitting colors of pixels included in the display panel DP, which will be described later. In addition, the anti-reflection layer may further include a black matrix adjacent to the color filters.

According to an embodiment of the present invention, the display module DM may include a display panel DP and an input sensor ISU.

The display panel DP may by any one among a liquid crystal display panel, an electrophoretic display panel, a microelectromechanical system display panel, an electrowetting display panel, an organic light emitting display panel, an inorganic light emitting display panel, and a quantum dot light emitting display panel. However, the embodiment of the inventive concept is not limited thereto. Hereinafter, the display panel DP will be described as an organic light emitting display panel.

The input sensor ISU may include any one among a capacitive sensor, an optical sensor, an ultrasonic sensor, and an electromagnetic induction sensor. The input sensor ISU may be formed on the display panel DP through a roll-to-roll process or may be separately manufactured and attached to an upper side of the display panel DP through an adhesive layer, and the embodiment of the inventive concept is not limited to any embodiment.

The display module DM may include a circuit board CB. The circuit board CB may include a driving chip DC and a printed circuit board CF. FIG. 10 shows an embodiment in which the driving chip DC is mounted on the display panel DP, but the embodiment of the inventive concept is not limited thereto. The driving chip DC may generate driving signals required for operation of the display panel DP based on control signals transmitted from the printed circuit board CF.

The display panel DP may include a bending region BA, and a first non-bending region NBA1 and a second non-bending region NBA2 spaced apart in the second direction DR2 with the bending region BA therebetween.

The bending region BA may be defined as a region where the display panel DP is bent along a virtual bending axis extending in the first direction DR1. The first non-bending region NBA1 may be defined as a region overlapping the transmission region TA, and the second non-bending region NBA2 may be defined as a region to which the printed circuit board CF is connected. Although not shown, when the bending region BA is bent with respect to a bending axis, the printed circuit board CF and the driving chip DC may be bent in a direction toward a rear surface of the display panel DP, and may thus be disposed below the rear surface of the display panel DP. Although not shown, additional components may be disposed to compensate for a step between the circuit board CB and the rear surface of the display panel DP, which is generated due to the bending region BA.

According to an embodiment, a width of the first non-bending region NBA1 in the first direction DR1 may be greater than widths of the bending region BA and the second non-bending region NBA2. However, the embodiment of the inventive concept is not limited thereto, and the width of the bending region BA in the first direction DR1 may be provided in a shape that becomes narrower from the first non-bending region NBA1 to the second non-bending region NBA2, and is not limited to any one embodiment.

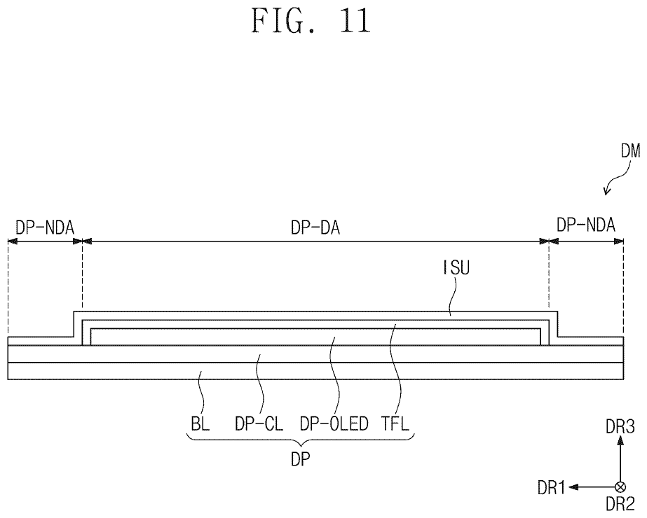

The accommodation member BC accommodates the display module DM and may be bonded with the window WM. The printed circuit board CF may be disposed on one end of the display panel DP and may be electrically connected to the circuit element layer DP-CL, which will be described with reference to FIG. 11. Although not shown, the display device DD may further include a main board, electronic modules mounted on the main board, a camera module, and a power module.

In the above, an example of the display device DD is described as a mobile phone terminal, but herein, the display device DD may include two or more electrically bonded electronic components. The display panel DP and the driving chip DC mounted on the display panel DP each correspond to a different electronic component, and the display device DD may be constituted with only these components, and is not limited to any one embodiment.

In an embodiment, the display device DD may be constituted only with the display panel DP and the printed circuit board CF connected to the display panel DP, and the display device DD may be constituted only with the main board and the electronic modules mounted on the main board.

FIG. 11 is a cross-sectional view of a display module shown in FIG. 10.

Referring to FIG. 11, the display panel DP may include a base layer BL, a circuit element layer DP-CL disposed on the base layer BL, a display element layer DP-OLED, and an upper insulating layer TFL. The input sensor ISU may be disposed on the upper insulating layer TFL.

The display panel DP may include a display region DP-DA and a non-display region DP-NDA. The display region DP-DA of the display panel DP may correspond to the display region DP-DA shown in FIG. 9 or the transmission region TA shown in FIG. 10, and the non-display region DP-NDA may correspond to the non-display region DD-NDA shown in FIG. 9 or the non-transmission region NTA shown in FIG. 10.

The base layer BL may include at least one plastic film. The base layer BL may include a plastic substrate, a glass substrate, a metal substrate, an organic/inorganic composite material substrate or the like as a flexible substrate.

The circuit element layer DP-CL may include at least one intermediate insulating layer and a circuit element layer. The intermediate insulating layer may include at least one intermediate inorganic layer or at least one intermediate organic layer. The circuit element may include signal lines, a pixel driving circuit, or the like.

The display element layer DP-OLED may include a plurality of organic light emitting diodes. The light emitting element layer DP-OLED may further include an organic layer such as a pixel defining film.

The upper insulating layer TFL may seal the display element layer DP-OLED. The upper insulating layer TFL may be disposed on the display element layer DP-OLED. The upper insulating layer TFL may overlap the display region DP-DA and the non-display region DP-NDA. The upper insulating layer TFL may overlap at least a portion of the non-display region DP-NDA. For example, the upper insulating layer TFL may include a thin film encapsulation layer. The thin film encapsulation layer may have a stack structure of an inorganic layer/an organic layer/an inorganic layer. The upper insulating layer TFL may serve to protect the light emitting element layer DP-OLED from moisture, oxygen, and foreign substances such as dust particles. However, the embodiment of the inventive concept is not limited thereto, and the upper insulating layer TFL may further include an additional insulating layer other than the thin film encapsulation layer. For example, an optical insulation layer for controlling refractive index may be further included.

In an embodiment of the inventive concept, an encapsulation substrate may be provided instead of the upper insulating layer TLF. In this case, the encapsulation substrate may face the base layer BL, and the circuit element layer DP-CL and the display element layer DP-OLED may be disposed between the encapsulation substrate and the circuit element layer DP-CL.

The input sensor ISU may be directly disposed on the display panel DP. Herein, “a component B is disposed directly on a component A” indicates that a separate layer is not disposed between the component A and the component B. In the present embodiment, the input sensor ISU may be manufactured through a roll-to-roll process with the display panel DP. However, the embodiment of the inventive concept is not limited thereto, and the input sensor ISU may be provided as an individual panel and bonded to the display panel DP through an adhesive layer. For example, the input sensor ISU may be omitted.

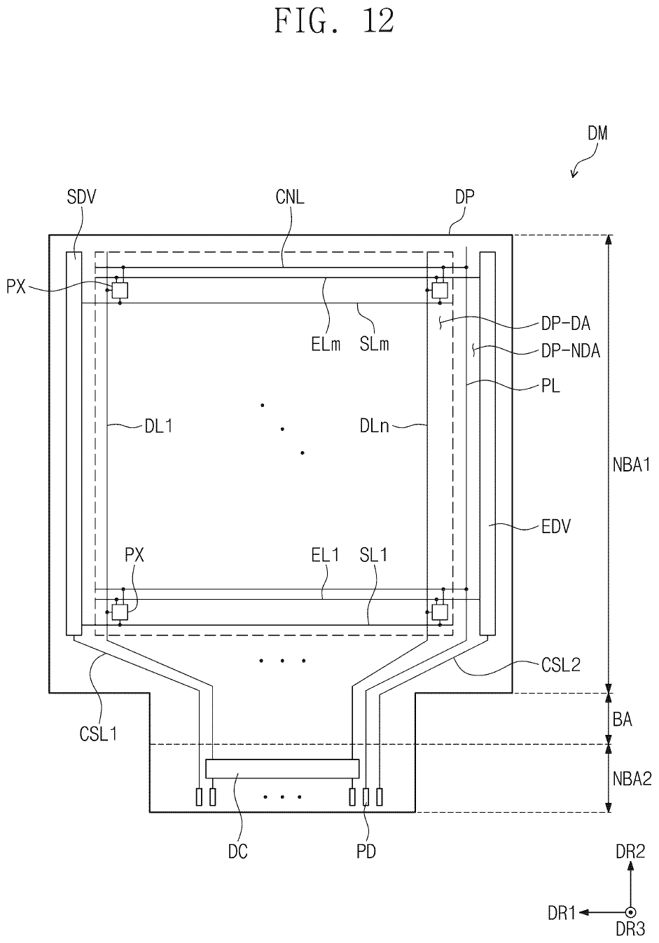

FIG. 12 is a plan view of a display panel shown in FIG. 11.

Referring to FIG. 12, the display module DM may include a display panel DP, a scan driver SDV, a data driver DC, and an emission driver EDV.

The display panel DP may include a first non-bending region NBA1, a second non-bending region NBA2, and a bending region BA between the first non-bending region NBA1 and the second non-bending region NBA2. The bending region BA may extend in the first direction DR1, and the first non-bending region NBA1, the bending region BA, and the second non-bending region NBA2 may be arranged in the second direction DR2.

The first non-bending region NBA1 may include a display region DP-DA and a non-display region DP-NDA around the display region DP-DA. The non-display region DP-NDA may surround the display region DP-DA. The display region DP-DA may be a region which displays images, and the non-display region DP-NDA may be a region which does not display images. The second non-bending region NBA2 and the bending region BA may be regions which do not display images.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, a power line PL, a plurality of connection lines CNL, and a plurality of pads PD. m and n are natural numbers. The pixels PX may be disposed in the display region DP-DA, and may be connected to the scan lines SL1 to SLm, the data lines DL1 to DLn, and the emission lines EL1 to ELm.

The scan driver SDV and the emission driver EDV may be disposed in the non-display region DP-NDA. The scan driver SDV and the emission driver EDV may be disposed in the non-display region DP-NDA adjacent to both sides of the first non-bending region NBA1, which are opposite to each other in the first direction DR1. The driving chip DC may be disposed in the second non-bending region NBA2. The driving chip DC may be manufactured in the form of an integrated circuit chip and mounted on the second non-bending region NBA2.

The scan lines SL1 to SLm may extend in the first direction DR1 and be connected to the scan driver SDV. The data lines DL1 to DLn may extend in the second direction DR2, and be connected to the driving chip DC via the bending region BA. The emission lines EL1 to ELm may extend in the second direction DR2 and be connected to the emission driver EDV.

The power line PL may extend to the second direction DR2 and be disposed in the non-display region DP-NDA. Although the power line PL is shown to be disposed between the display region DP-DA and the emission driver EDV, the embodiment of the inventive concept is not limited thereto, and the power line PL may be disposed between the display region DP-DA and the scan driver SDV.

The power line PL may extend to the second non-bending region NBA2 via the bending region BA. When viewed on a plane, the power line PL may extend towards a lower end of the second non-bending region NBA2. The power line PL may receive a driving voltage.

The connection lines CNL may extend to the first direction DR1 and be arranged in the second direction DR2. The connection lines CNL may be connected to the power line PL and the pixels PX. The driving voltage may be applied to the pixels PX through the power line PL1 and the connection lines CNL connected to each other.

The first control line CSL1 may be connected to the scan driver SDV, and may extend toward the lower end of the second non-bending region NBA2 via the bending region BA. The second control line CSL2 may be connected to the emission driver EDV, and may extend toward the lower end of the second non-bending region NBA2 via the bending region BA. The driving chip DC may be disposed between the first control line CSL1 and the second control line CSL2.

When viewed on a plane, the pads PD may be disposed adjacent to the lower end of the second non-bending region NBA2. The driving chip DC, the power line PL, the first control line CSL1, and the second control line CSL2 may be connected to the pads PD.

The data lines DL1 to DLn may be connected to corresponding pads PD through the driving chip DC. For example, the data lines DL1 to DLn may be connected to the driving chip DC, and the driving chip DC may be connected to the pads PD respectively corresponding to the data lines DL1 to DLn.

Although not shown, a printed circuit board may be connected to the pads PD, and a timing controller and a voltage generator may be disposed on the printed circuit board. The timing controller may be manufactured as an integrated circuit chip and mounted on the printed circuit board. The timing controller and the voltage generator may be connected to the pads PD through the printed circuit board.

The timing controller may control the operation of the scan driver SDV, the driving chip DC, and the emission driver EDV. The timing controller may generate a scan control signal, a data control signal, and an emission control signal in response to control signals received from the outside. The voltage generator may generate a driving voltage.

The scan control signal may be provided to the scan driver SDV through the first control line CSL1. The emission control signal may be provided to the emission driver EDV through the second control line CSL2. The data control signal may be provided to the driving chip DC. The timing controller receives image signals from the outside, and may convert the data format of the image signals to match interface specifications with the driving chip DC and provide the image signals with converted data format to the driving chip DC.

The scan driver SDV may generate a plurality of scan signals in response to the scan control signal. The scan signals may be applied to the pixels PX through the scan lines SL1 to SLm. The scan signals may be sequentially applied to the pixels PX.

The driving chip DC may generate a plurality of data voltages corresponding the image signals in response to the data control signal. The data voltages may be applied to the pixels PX through the data lines DL1 to DLn. The emission driver EDV may generate a plurality of emission signals in response to the emission control signal. The emission signals may be applied to the pixels PX through the emission lines EL1 to ELm.

The pixels PX may be provided with the data voltages in response to the scan signals. The pixels PX may display an image by emitting light of luminance corresponding to the data voltages in response to the light emitting signals. The emission duration of the pixels PX may be controlled by the emission signals.

FIG. 13 is a view showing a cross-section of the display panel corresponding to any one pixel shown in 12 as an example.

As an example, in FIG. 13, the upper insulating layer TFL may be described to include a thin film encapsulation layer.

Referring to FIG. 13, the pixels PX may include a transistor TR and a light emitting element OLED. The light emitting element OLED may include a first electrode AE (or an anode), a second electrode CE (or a cathode), a hole control layer HCL, an electron control layer ECL, and an emission layer EML.

The transistor TR and the light emitting element OLED may be disposed on a substrate SUB. Although one transistor TR is shown as an example, the pixels PX may include a plurality of transistors and at least one capacitor for driving the light emitting element OLED.

The display region DP-DA may include a light emitting region PA corresponding to each of the pixels PX and a non-light emitting region NPA around the light emitting region PA. The light emitting element OLED may be disposed in the light emitting region PA.

A buffer layer BFL is disposed on the substrate BL, and the buffer layer BFL may be an inorganic layer. A semiconductor pattern may be disposed on the buffer layer BFL. The semiconductor pattern may include polysilicon or amorphous silicon. When the semiconductor pattern includes polysilicon or amorphous silicon, a silicon film of the semiconductor pattern may be crystallized by the laser device DMA shown in FIG. 1.

The semiconductor pattern may be doped with an N-type dopant or a P-type dopant. The semiconductor pattern may include a heavily doped region and a lightly doped region. The heavily doped region has greater conductivity than the lightly doped region, and may substantially serve as a source electrode and a drain electrode of the transistor TR. The lightly doped region may substantially correspond to an active (or a channel) of the transistor.

A source S, an active A, and a drain D of the transistor TR may be formed from the semiconductor pattern. A first insulating layer INS1 may be disposed on the semiconductor pattern. A gate G of the transistor TR may be disposed on the first insulating layer INS1. A second insulating layer INS2 may be disposed on the gate G. A third insulating layer INS3 may be disposed on the second insulating layer INS2.

The connection electrode CNE may include a first connection electrode CNE1 and a second connection electrode CNE2 to connect the transistor TR and the light emitting element OLED. The first connection electrode CNE1 may be disposed on the third insulating layer INS3 and be connected to the drain D through a first contact hole CH1 defined in the first to third insulating layers INS1 to INS3.

A fourth insulating layer INS4 may be disposed on the first connection electrode CNE1. A fifth insulating layer INS5 may be disposed on the fourth insulating layer INS4. The second connection electrode CNE2 may be disposed on the fifth insulating layer INS5. The second connection electrode CNE2 may be connected to the first connection electrode CNE1 through a second contact hole CH2 defined in the fourth and fifth insulating layers INS4 and INS5.

A sixth insulating layer INS6 may be disposed on the second connection electrode CNE2. A layer from the buffer layer BFL to the sixth insulating layer INS6 may be defined as a circuit element layer DP-CL. The first insulating layer INS1 to the sixth insulating layer INS6 may be an inorganic layer or an organic layer.

The first electrode AE may be disposed on the sixth insulating layer INS6. The first electrode AE may be connected to the second connection electrode CNE2 through a third contact hole CH3 defined in the sixth insulating layer INS6. A pixel defining film PDL in which an opening PX_OP for exposing a predetermined portion of the first electrode AE is defined may be disposed on the first electrode AE and the sixth insulating layer INS6.

The hole control layer HCL may be disposed on the first electrode AE and the pixel defining film PDL. The hole control layer HCL may include a hole transport layer and a hole injection layer.

The emission layer EML may be disposed on the hole control layer HCL. The emission layer EML may be disposed in a region corresponding to the opening PX_OP. The emission layer EML may include an organic material or an inorganic material. For example, the emission layer EML may generate any one among red light, green light, and blue light.

The electron control layer ECL may be disposed on the emission layer EML and the hole control layer HCL. The electron control layer ECL may include an electron transport layer and an electron injection layer. The hole control layer HCL and the electron control layer ECL may be commonly disposed in the light emitting region PA and the non-light emitting region NPA.

The second electrode CE may be disposed on the electron control layer ECL. The second electrode CE may be commonly disposed in the pixels PX. A layer on which the light emitting element OLED is disposed may be defined as the display element layer DP-OLED.

The thin film encapsulation layer TFL may be disposed on the second electrode CE to cover the pixels PX. The thin film encapsulation layer TFL may include a first encapsulation layer EN1 disposed on the second electrode CE, a second encapsulation layer EN2 disposed on the first encapsulation layer EN1, and a third encapsulation layer EN3 disposed on the second encapsulation layer EN2.

The first and third encapsulation layers EN1 and EN3 may include an inorganic insulating layer and may protect the pixels PX from moisture/oxygen. The second encapsulation layer EN2 may include an organic insulating layer and may protect the pixels PX from foreign substances such as dust particles.

A first voltage may be applied to the first electrode AE through the transistor TR, and a second voltage having a lower level than the first voltage may be applied to the second electrode CE. Holes and electrons injected into the emission layer EML combine to form excitons, and the excitons transition to a ground state, and accordingly the light emitting element OLED may emit light.

An input sensing unit ISP may be disposed on the thin film encapsulation layer TFL. The input sensing unit ISP may be directly manufactured on an upper surface of the thin film encapsulation layer TFL.

A base layer (not shown) may be disposed on the thin film encapsulation layer TFL. The base layer may include an inorganic insulating layer. At least one inorganic insulating layer may be provided as the base layer.

According to an embodiment of the inventive concept, parameters of a plurality of laser beams for crystallizing a silicon film are obtained, and using the parameters, individual waveforms of the plurality of laser beams and waveforms of process laser beams defined by the combined laser beams thereof may be measured in real time. Accordingly, the process laser beams for crystallizing a silicon film may be checked in real time, and thus, the silicon film may have improved crystallization reliability.

Although embodiments of the present inventive concepts have been described, various modifications and similar arrangements of such embodiments will be apparent to a person of ordinary skill in the art. Accordingly, the inventive concepts are not limited to such embodiments, but rather to the scope and spirit of the appended claims.

What is claimed is:

1. A method of manufacturing a display device, the method comprising:
oscillating a plurality of laser beams from a plurality of laser generators;
measuring first parameters of each of the laser beams by a first measuring unit;
measuring second parameters of each of the laser beams after passing through an optical system by a process measuring unit;
obtaining optical functions through the first parameters and the second parameters;
obtaining a correction function using the optical functions; and
irradiating a substrate with the laser beams, based on the optical functions and the correction function.

2. The method of claim 1, wherein the measuring of the second parameters of each of the laser beams comprises blocking all other laser beams except for any one of the laser beams from being incident to the optical system by a blocking unit.

3. The method of claim 1, wherein the first parameters and the second parameters each comprise values for pulse max intensity, pulse 2^{nd} hump max intensity, and time integral of pulse.

4. The method of claim 3, wherein the obtaining of the optical functions comprises:
comparing the pulse max intensity of each of the first parameters and the pulse max intensity of each of the second parameters to obtain first numerical values;
comparing the pulse 2^{nd} hump max intensity of each of the first parameters and the pulse 2^{nd} hump max intensity of each of the second parameters to obtain second numerical values; and
comparing the integral of pulse of each of the first parameters and the integral of pulse of each of the second parameters to obtain third numerical values.

5. The method of claim 4, wherein the obtaining of the optical functions uses an average value of corresponding first, second, and third numerical values among the first, second, and third numerical values.

6. The method of claim 1, further comprising:
obtaining a first theoretical parameter of a first process laser beam;
obtaining a first actual parameter of the first process laser beam; and
obtaining the correction function, using the first theoretical parameter and the first actual parameter,
wherein the first process laser beam is a mixed laser beam of the laser beams oscillated at a same time point,
the first theoretical parameter of the first process laser beam is calculated using the optical functions, and
the first actual parameter of the first process laser beam is measured by the process measuring unit.

7. The method of claim 1, wherein the irradiating of the substrate with the laser beams, based on the optical functions and the correction function comprises setting an oscillation time point of at least one of the laser beams differently.

8. The method of claim 7, wherein the irradiating of the substrate with the laser beams, based on the optical functions and the correction function further comprises:
obtaining a second theoretical parameter of a second process laser calculated by applying the optical functions and the correction function to the laser beams oscillated at different time points;
obtaining a second actual parameter of the second process laser measured by the process measuring unit; and
comparing the second theoretical parameter with the second actual parameter, and
wherein the second process laser beam is a mixture of the laser beams oscillated at different time points.

9. The method of claim 8, wherein the irradiating of the substrate with the laser beams, based on the optical functions and the correction function further comprises checking the laser generators or the optical system when the second theoretical parameter is out of a predetermined range from the second actual parameter, and
the measuring of the first parameter is performed after checking the laser generators or the optical system.

10. The method of claim 8, wherein the irradiating of the substrate with the laser beams, based on the optical functions and the correction function further comprises comparing a third theoretical parameter and a third actual parameter of the second process laser beam when the second theoretical parameter is within a predetermined range from the second actual parameter, and
the third theoretical parameter of the second process laser beam is calculated in real time, and the third actual parameter of the second process laser beam is measured in real time by the process measuring unit.

11. The method of claim 10, wherein the irradiating of the substrate with the laser beams, based on the optical functions and the correction function further comprises regulating the oscillation time points of the laser beams when the third theoretical parameter of the second process laser beam is out of a predetermined range from the third actual parameter.

12. The method of claim 10, wherein the irradiating of the substrate with the laser beams, based on the optical functions and the correction function further comprises operating a facility when the third theoretical parameter is within a predetermined range from the third actual parameter.

13. A laser device comprising:
laser generators configured to oscillate a plurality of laser beams;
a first measuring unit configured to measure parameters of each of the laser beams;
a blocking unit configured to selectively block the laser beams oscillated from the laser generator;
an optical system configured to mix the laser beams emitted from the laser generator into a single process laser beam; and
a process measuring unit configured to measure parameters of the laser beams emitted from the optical system and the process laser beam.

14. The laser device of claim 13, wherein the parameters each comprise values for pulse max intensity, pulse 2^{nd} hump max intensity, and time integral of pulse.

15. The laser device of claim 14, further comprising a controller configured to obtain a plurality of optical functions by comparing first parameters defined as the parameters of the laser beams measured by the first measuring unit with second parameters defined as the parameters of the laser beams measured by the process measuring unit.

16. The laser device of claim 15, wherein the controller obtains the optical functions, using first numerical values obtained by comparing pulse max intensity of each of the first parameters and pulse max intensity of each of the second parameters, second numerical values obtained by comparing pulse 2^{nd} hump max intensity of the first parameters and pulse 2^{nd} hump max intensity of the second parameters, and third numerical values obtained by comparing integral of pulse of the first parameters and integral of pulse of the second parameters.

17. The laser device of claim 15, wherein the controller calculates a first theoretical parameter defined as a parameter of the process laser beam calculated using the optical functions.

18. The laser device of claim 17, wherein the controller compares the first theoretical parameter with a first actual parameter defined as a parameter of the process laser beam obtained by the process measuring unit.

19. The laser device of claim 18, wherein the controller obtains a correction function, using the first theoretical parameter and the first actual parameter.

20. The laser device of claim 15, wherein the blocking unit blocks all other laser beams to allow any one of the plurality of laser beams to enter the optical system when the second parameter of each of the laser beams is measured by the process measuring unit.
